(19) United States
(12) Patent Application Publication
(10) Pub. No.: US 2007/0099433 A1
(43) Pub. Date: May 3, 2007

(54) GAS DIELECTRIC STRUCTURE FORMATION USING RADIATION

(75) Inventors: Brett H. Engel, Hopewell Junction, NY (US); Dermott A. MacPherson, Pleasant Valley, NY (US); Aaron D. Shore, Poughkeepsie, NY (US)

Correspondence Address: HOFFMAN, WARNICK & D'ALESSANDRO LLC, 75 STATE ST, 14TH FL, ALBANY, NY, 12207, US

(73) Assignee: INTERNATIONAL BUSINESS MACHINES CORPORATION, ARMONK, NY (US)

(21) Appl. No.: 11/163,909

(22) Filed: Nov. 3, 2005

(51) Int. Cl. H01L 21/31; H01L 21/469

(52) U.S. Cl. 438/758

(57) ABSTRACT

Methods and resulting structure of forming a gas dielectric structure in an interconnect structure are disclosed. In one embodiment, the method includes providing the interconnect structure including at least one interconnect layer having a dielectric, at least one conductor and a first cap layer; and causing the dielectric to contract to form the gas dielectric structure by exposing the interconnect structure to radiation. The radiation can be electron beam radiation or UV radiation. In one embodiment, an interface-breaking enhancing film can be used to selectively locate the gas dielectric structures formed.

### BACKGROUND OF THE INVENTION

1. Technical Field

The present invention relates generally to semiconductor interconnect structures, and more particularly, to methods of forming a gas dielectric structure for a semiconductor interconnect structure using radiation.

2. Related Art

In order to enhance semiconductor chip operational speed, semiconductor devices have been continuously scaled down in size. Unfortunately, as semiconductor device size is decreased, the capacitive coupling between conductors in a circuit tends to increase since the capacitive coupling is inversely proportional to the distance between the conductors. This coupling may ultimately limit the speed of the chip or otherwise inhibit proper chip operation if steps are not taken to reduce the capacitive coupling.

The capacitance between conductors is also dependent on the insulator, or dielectric, used to separate the conductors. Traditional semiconductor fabrication commonly employs silicon dioxide (SiO₂) as a dielectric, which has a dielectric constant (k) of approximately 3.9. One challenge facing further development is finding materials with a lower dielectric constant that can be used between the conductors. As the dielectric constant of such materials is decreased, the speed of performance of the chip is increased. Some new low-k dielectric materials that have been used to provide a lower dielectric constant between conductors include, for example, fluorinated glass and organic materials. Unfortunately, provision of newer low-k dielectric materials presents a number of new challenges, which increase process complexity and cost.

Implementation of organic materials to reduce the dielectric constant also reduces the overall back-end-of-line (BEOL) capacitance. Unfortunately, organic materials suffer from temperature limitations, shrinkage or swelling during manufacturing or chip operation, and poor structural integrity. Instead of using silicon dioxide (SiO₂), another approach is to implement gas, such as air, which is provided in the form of a gas dielectric structure in a semiconductor structure. Air has the lowest effective dielectric constant. Simple capacitance modeling of parallel wires shows that even a small air-gap near the wires results in a significant improvement in the overall dielectric constant (k) for a structure, e.g., a 10% air gap per edge will reduce the effective dielectric constant of a dielectric by approximately 15%. Current processing for implementing gas dielectric structures, however, is fairly complex and cannot be easily integrated. As a result, completely new integration schemes have been developed, which are more complex and more costly. For example, typical gas dielectric structure formation requires additional masking layers for reactive ion etching (RIE) processing steps relative to damascene wire formation.

In view of the foregoing, there is a need for an improved solution for forming a gas dielectric structure for a semiconductor interconnect structure.

### SUMMARY OF THE INVENTION

Methods and resulting structure of forming a gas dielectric structure in an interconnect structure are disclosed. In one embodiment, the method includes providing the interconnect structure including at least one interconnect layer having a dielectric, at least one conductor and a first cap layer; and causing the dielectric to contract to form the gas dielectric structure by exposing the interconnect structure to radiation. The radiation can be electron beam radiation or ultraviolet (UV) radiation. In one embodiment, an interface-breaking enhancing film can be used to selectively locate the gas dielectric structures formed.

A first aspect of the invention is directed to a method of forming a gas dielectric structure in an interconnect structure, the method comprising the steps of: providing the interconnect structure including at least one interconnect layer having a dielectric, at least one conductor and a first cap layer; and causing the dielectric to contract to form the gas dielectric structure by exposing the interconnect structure to radiation.

A second aspect of the invention includes a method of forming a gas dielectric structure in an interconnect structure, the method comprising the steps of: providing the interconnect structure including an interlevel dielectric, at least one conductor and a first cap layer above the interlevel dielectric and a second cap layer below the interlevel dielectric; and causing the interlevel dielectric to contract from at least one of the first cap layer, the second cap layer and the at least one conductor to form the gas dielectric structure by exposing the interconnect structure to electron beam radiation.

A third aspect of the invention related to an interconnect structure comprising: a dielectric layer including at least one conductor positioned therein; at least one cap layer adjacent the dielectric layer; and at least one gas dielectric structure positioned within the dielectric layer, wherein the gas dielectric structure has a substantially arcuate shape extending from the at least one cap layer.

The foregoing and other features of the invention will be apparent from the following more particular description of embodiments of the invention.

### BRIEF DESCRIPTION OF THE DRAWINGS

The embodiments of this invention will be described in detail, with reference to the following figures, wherein like designations denote like elements, and wherein:

FIG. 1 shows an interconnect structure provided according to one embodiment of the invention.

FIG. 2 shows the interconnect structure of FIG. 1 having a gas dielectric structure formed therein according to one embodiment of the invention.

FIG. 3 shows an alternative embodiment of one step of a method according to one embodiment of the invention

### DETAILED DESCRIPTION

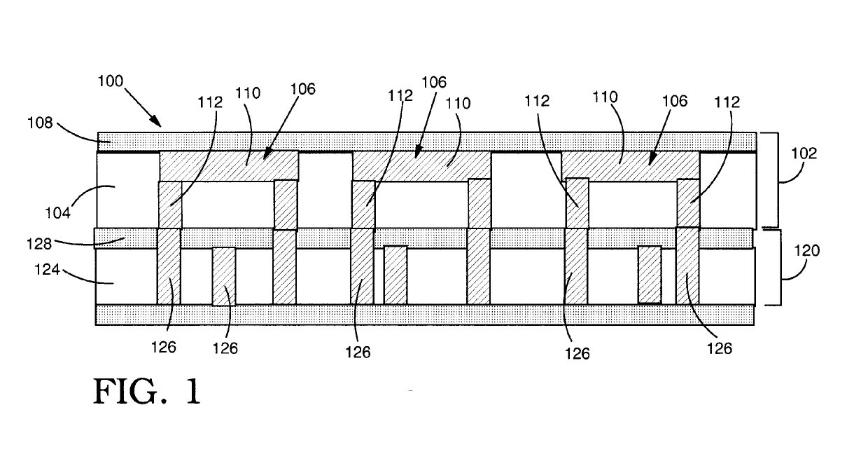

With reference to the accompanying drawings, various embodiments of methods of forming a gas dielectric structure in an interconnect structure will now be described. FIG. 1 shows an illustrative interconnect structure 100 provided according to a first step. It should be recognized that interconnect structure 100 is only illustrative of various interconnect structures to which the invention can be applied. Interconnect structure 100 includes at least one interconnect layer 102 having an (interlevel) dielectric 104, at least one conductor 106 and a first cap layer 108. Dielectric 104 can be any now known or later developed high dielectric constant (HiK) organic dielectric material (no glass) such as hydrogenated silicon oxycarbide (SiCOH), SILK™ (from Dow Chemical), etc. Conductor(s) 106 can be any now known or later developed interconnect conductive material, e.g., copper (Cu), aluminum (Al), etc. Conductor(s) 106 can include lines 110, vias 112 and/or combinations thereof. Cap layer 108 can be any conventional cap layer such as silicon nitride (Si₃N₄) or silicon dioxide (SiO₂). The particular interconnect structure 100 also may include a second interconnect layer 120 including a second dielectric 124, at least one conductor 126 (FIG. 1) and a second cap layer 128. Second interconnect layer 120 may include substantially similar materials as that of first interconnect layer 102, or different materials.

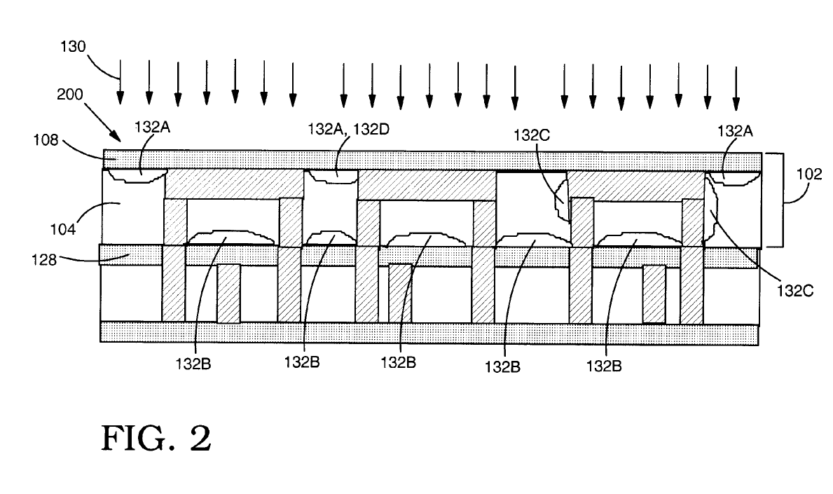

Turning to FIG. 2, in a next step according to one embodiment of the invention, interconnect structure 100, i.e., at least dielectric 104, is exposed to radiation 130, which causes dielectric 104 to cure. As shown, as curing occurs, radiation 130 causes dielectric 104 to contract to form a gas dielectric structure 132A-132C. In one embodiment, radiation 130 can include electron beam radiation (preferred) or ultraviolet (UV) radiation. The electron beam radiation or UV radiation can be generated in any now known or later developed fashion, e.g., for e-beam, via a scanning electron microscope or similar electron beam generating structure.

In any event, the exposure must be sufficiently long enough and have energy (e.g., acceleration voltage for e-beam) sufficient to pierce cap layer 108 to interact with dielectric 104. Where electron beam radiation is used, a dose of approximately 300 micro-Coulombs/cm² has been found advantageous. In one embodiment, this dose may be achieved using electron beam radiation of no less than approximately 2 KeV and no greater than approximately 10 KeV, for no less than approximately 1 minute and no greater than approximately 8 minutes. In addition, electron beam radiation preferably has an energy of no less than approximately 300 Pascal and no greater than 1 giga-Pascal. In one particular example, a silicon nitride (Si₃N₄) cap layer having a thickness of approximately 3000 Å and a density of approximately 1.3 g/cm³, was exposed to electron beam radiation of approximately 3 KeV for approximately 2-3 minutes, which resulted in the above-described dose. The above-described parameters may vary, however, depending on the type of cap layer 108 used and its thickness.

Continuing with FIG. 2, gas dielectric structure 132A-C can be formed in a number of different locations within dielectric 104. Gas dielectric structures 132A illustrate structures in which dielectric 104 contracts vertically from first cap layer 108. Gas dielectric structures 132B illustrate structures in which dielectric 104 contracts vertically from second (lower) cap layer 128, even under line conductors 110. Gas dielectric structures 132C illustrate structures in which dielectric 104 contracts laterally from at least one of conductor(s) 106. It should be recognized that gas dielectric structures 132A-C can occur individually or in combinations. For example, dielectric 104 may contract at least vertically from first cap layer 108 alone, or it may contract at least vertically from second cap layer 128, opposite first cap layer 108.

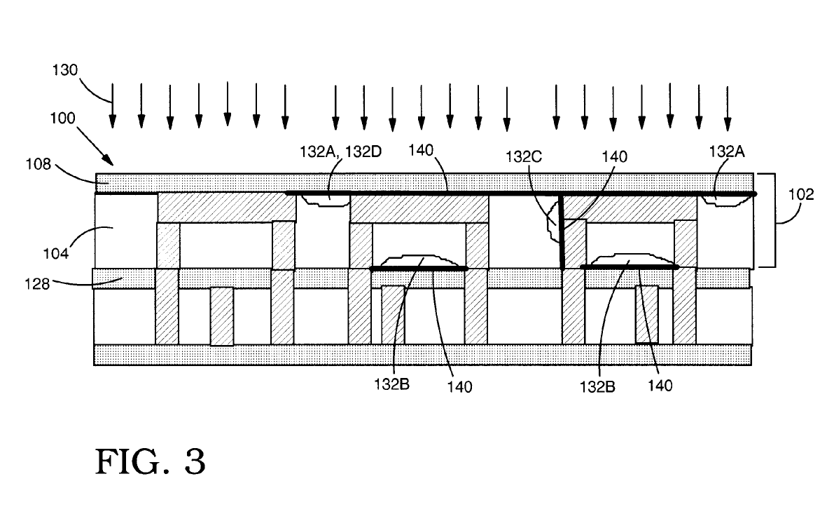

Turning to FIG. 3, in one alternative embodiment, where breaking of an interface between dielectric 104 and the other materials, e.g., conductor 106 and/or cap layer 108, using radiation is difficult, an interface-breaking enhancing film 140 may be selectively formed prior to formation of the other materials, i.e., as part of formation of interconnect structure 100. Interface-breaking enhancing film 140 may also be selectively provided at location(s) at which a gas dielectric structure 132A-C is desired, and omitted where a gas dielectric structure 132A-C is not desired. In this fashion, the positioning of gas dielectric structures 132A-C can be selectively optimized. Film 140 may include any material that reduces the energy required to break the interface between the particular materials, which fosters formation of gas dielectric structures 132A-C by reducing the energy required.

The above-described methodology can be carried out after each cap layer is formed and at each level.

The resulting interconnect structure 200 (FIG. 2) includes dielectric layer 104 including at least one conductor 106 positioned therein, at least one cap layer 108, 128 adjacent dielectric layer 104; and at least one gas dielectric structure 132A-C positioned within dielectric layer 104. In one embodiment, each gas dielectric structure 132A-C has a substantially arcuate shape extending from the at least one cap layer 108, 128. In addition, at least one gas dielectric structure 132C has a substantially arcuate shape extending from at least one of conductor(s) 106. It should also be recognized that gas dielectric structures 132A-C may have different shapes in some circumstances. For example, gas dielectric structure 132D is not arcuate.

While this invention has been described in conjunction with the specific embodiments outlined above, it is evident that many alternatives, modifications and variations will be apparent to those skilled in the art. Accordingly, the embodiments of the invention as set forth above are intended to be illustrative, not limiting. Various changes may be made without departing from the spirit and scope of the invention as defined in the following claims.

What is claimed is:

1. A method of forming a gas dielectric structure in an interconnect structure, the method comprising the steps of:
providing the interconnect structure including at least one interconnect layer having a dielectric, at least one conductor and a first cap layer; and
causing the dielectric to contract to form the gas dielectric structure by exposing the interconnect structure to radiation.

2. The method of claim 1, wherein the exposing step causes the dielectric to contract at least vertically from the first cap layer.

3. The method of claim 1, wherein the exposing step causes the dielectric to contract at least vertically from the first cap layer and a second cap layer opposite the first cap layer.

4. The method of claim 1, wherein the exposing step causes the dielectric to contract laterally from at least one of the at least one conductor.

5. The method of claim 1, wherein the exposing step achieves a dose of approximately 300 micro-Coulombs/cm².

6. The method of claim 1, wherein the exposing step includes using electron beam radiation of no less than approximately 2 KeV and no greater than approximately 10 KeV.

7. The method of claim 1, wherein the exposing step lasts for no less than approximately 1 minute and no greater than approximately 8 minutes.

8. The method of claim 1, wherein the exposing step includes using electron beam radiation having an energy of no less than approximately 300 Pascal and no greater than 1 giga-Pascal.

9. The method of claim 1, wherein the radiation includes one of electron beam radiation and ultraviolet radiation.

10. The method of claim 1, wherein the providing step further includes providing an interface-breaking enhancing film at a location at which the gas dielectric structure is desired.

11. A method of forming a gas dielectric structure in an interconnect structure, the method comprising the steps of:
providing the interconnect structure including an interlevel dielectric, at least one conductor and a first cap layer above the interlevel dielectric and a second cap layer below the interlevel dielectric; and
causing the interlevel dielectric to contract from at least one of the first cap layer, the second cap layer and the at least one conductor to form the gas dielectric structure by exposing the interconnect structure to electron beam radiation.

12. The method of claim 11, wherein the exposing step causes the dielectric to contract laterally from the at least one conductor.

13. The method of claim 11, wherein the exposing step achieves a dose of approximately 300 micro-Coulombs/cm².

14. The method of claim 11, wherein the exposing step includes using electron beam radiation of no less than approximately 2 KeV and no greater than approximately 10 KeV.

15. The method of claim 11, wherein the exposing step lasts for no less than approximately 1 minute and no greater than approximately 8 minutes.

16. The method of claim 11, wherein the exposing step includes using electron beam radiation having an energy of no less than approximately 300 Pascal and no greater than 1 giga-Pascal.

17. The method of claim 11, wherein the providing step further includes providing an interface-breaking enhancing film at a location at which the gas dielectric structure is desired.

18. An interconnect structure comprising:
a dielectric layer including at least one conductor positioned therein;
at least one cap layer adjacent the dielectric layer; and
at least one gas dielectric structure positioned within the dielectric layer, wherein the gas dielectric structure has a substantially arcuate shape extending from the at least one cap layer.

19. The interconnect structure of claim 18, wherein the at least one gas dielectric structure includes a plurality of gas dielectric structures.

20. The interconnect structure of claim 18, wherein at least one gas dielectric structure has a substantially arcuate shape extending from at least one of the at least one conductor.
